(19) United States
(12) Patent Application Publication
(10) Pub. No.: US 2010/0058152 A1
(43) Pub. Date: Mar. 4, 2010

(54) DECODING APPARATUS AND METHOD

(75) Inventor: Kohsuke HARADA, Yokohama-shi (JP)

Correspondence Address: Charles N.J. Ruggiero, Esq.;Ohlandt, Greeley, Ruggiero & Perle, L.L.P., One Landmark Square, 10th Floor, Stamford, CT, 06901-2682, US

(73) Assignee: KABUSHIKI KAISHA TOSHIBA

(21) Appl. No.: 12/406,663

(22) Filed: Mar. 18, 2009

(30) Foreign Application Priority Data
Sep. 4, 2008 (JP) 2008-226904

(51) Int. Cl. H03M 13/41; G06F 11/10

(52) U.S. Cl. 714/795; 714/E11.032

(57) ABSTRACT

A-decoding-apparatus includes first-equalization-unit configured to obtain an-equalized-bit-string subjected to hard-decision by equalizing the-input-signal, and to obtain reliability-value-data as soft-decision which is indicating reliability of the-hard-decision with respect to each bit of the-equalized-bit-string, second-equalization-unit configured to obtain a plurality of candidates of the-equalized-bit-string subjected to hard-decision by equalizing the-first-signal, conversion-unit configured to covert the-reliability-value-data corresponding to the-candidates of the-equalized-bit-string, decoding-unit configured to obtain a-bit-string by performing error-correction decoding by using the-converted-reliability-value-date as soft-decision on the-reliability-value-data, determination-unit configured to determine whether the-bit-string obtained by the-decoding-unit contains an-error, and control-unit configured to control the-conversion-unit and the-decoding-unit based on determination-result obtained by the-determination-unit to repeatedly execute processing of causing the-conversion-unit to convert the-reliability-value-data corresponding to the-candidate of the-equalized-bit-string and causing the-decoding-unit to decode the-reliability-value-data converted by the-conversion-unit, until a-bit-string without error is obtained.

### CROSS-REFERENCE TO RELATED APPLICATIONS

This application is based upon and claims the benefit of priority from prior Japanese Patent Application No. 2008-226904, filed Sep. 4, 2008, the entire contents of which are incorporated herein by reference.

### BACKGROUND OF THE INVENTION

1. Field of the Invention

The present invention relates to a decoding apparatus which decodes, for example, a signal received via a communication channel or a signal read out from a recording medium into data.

2. Description of the Related Art

As is generally known, a partial response (PR) scheme is available as a signal processing scheme for performing high-speed communication or high-density recording via a band-limited communication channel (see, for example, Japanese Patent No. 3567067). In general, transmission waveforms in radio communication maintain the Nyquist criterion to prevent signal waveforms corresponding to respective data samples from interfering with each other.

In contrast to this, the PR scheme implements high-speed communication or high-density recording by permitting interference between samples and increasing the amount of data which can be transmitted per unit time. The PR scheme is, however, designed to receive a reception signal at a signal point different from that of a transmission signal so as to permit interference between samples. For this reason, the PR scheme requires equalization processing to obtain reception signals without interference on the receiving side.

As an equalization scheme applied to the PR scheme, Viterbi equalization is generally used. Viterbi equalization is often used as a Viterbi decoder when, for example, a convolutional code is decoded. Viterbi equalization is an equalization method of performing maximum likelihood sequence estimation for a signal sequence having a Markov process containing noise.

In general, a maximum likelihood estimation sequence obtained by Viterbi equalization in the PR scheme is used as a reception sequence from which interference is removed. Even in a signal from which interference is removed by Viterbi equalization, an estimated sequence may contain an error due to the influences of noise and other disturbances.

In order to reduce the influence of an estimation result error due to a disturbance on the receiving side, list Viterbi equalization is used as a method of obtaining a plurality of estimation results from maximum likelihood estimation candidates in descending order of probability of correctness in Viterbi equalization.

Using list Viterbi equalization can obtain a plurality of estimation results with high probability. If, therefore, some unit allowing error detection such as an error detection code is embedded in transmission data in advance, the error rate characteristic on the receiving side can be improved by performing reception processing on the receiving side, upon detection of an equalization result error, by selecting another estimation candidate. This technique is based on the principle that a plurality of estimation results with high probability of correctness obtained by Viterbi equalization are likely to include a truly correct estimation result.

Recently, in an ECC (Error Correcting Codes) scheme of embedding an error correcting code in transmission data in advance on the transmitting side, for example, a turbo code or an LDPC (Low Density Parity Check) code is used. This technique requires soft-valued reliability information on the receiving side.

When, however, soft-valued reliability information is obtained by list Viterbi equalization for each of a plurality of estimation sequences with high probability, the arithmetic processing amount increases, resulting in poor efficiency. This requires a method of efficiently deriving a soft reliability value for each of a plurality of equalization candidates.

As systems using the PR scheme, the MSK (Minimum Shift Keying) scheme used in GSM (Global System for Mobile Communications), the PR-ML (Partial Response-Maximum Likelihood) scheme in a magnetic recording system, and the like are available.

Conventionally, when list Viterbi equalization and the error correcting scheme requiring soft-valued reliability information are used on the signal receiving side, since accurate reliability information is provided for each of a plurality of estimation results with high probability of correctness by list Viterbi equalization, the degree of complexity of Viterbi equalization processing considerably increases, resulting in poor efficiency.

### BRIEF SUMMARY OF THE INVENTION

The present invention has been made to solve the above problem, and has as its object to provide a decoding apparatus and method which can efficiently perform equalization processing.

An aspect of the present invention is provides an decoding apparatus comprising, a first equalization unit configured to obtain an equalized bit string subjected to hard decision by equalizing the input signal, and to obtain reliability value data as soft decision which is indicating reliability of the hard decision with respect to each bit of the equalized bit string, a second equalization unit configured to obtain a plurality of candidates of the equalized bit string subjected to hard decision by equalizing the first signal, a conversion unit configured to covert the reliability value data corresponding to the candidates of the equalized bit string, a decoding unit configured to obtain a bit string by performing error correction decoding by using the converted reliability value date as soft decision on the reliability value data, a determination unit configured to determine whether the bit string obtained by the decoding unit contains an error, and a control unit configured to control the conversion unit and the decoding unit based on a determination result obtained by the determination unit to repeatedly execute processing of causing the conversion unit to convert the reliability value data corresponding to the candidate of the equalized bit string and causing the decoding unit to decode the reliability value data converted by the conversion unit, until a bit string without error is obtained.

### BRIEF DESCRIPTION OF THE SEVERAL VIEWS OF THE DRAWING

FIG. 1 is a block diagram showing the arrangement of a data transmission system according to a first embodiment;

FIG. 2 is a graph showing a simulation result in the data transmission system shown in FIG. 1;

FIG. 3 is a block diagram showing a modification of the data transmission system shown in FIG. 1;

FIG. 4 is a block diagram showing the arrangement of a data transmission system according to a second embodiment;

FIG. 5 is a flowchart for explaining the operation of the decoding apparatus shown in FIG. 4;

FIG. 6 is a block diagram showing a modification of the data transmission system shown in FIG. 4;

FIG. 7 is a flowchart for explaining the operation of the decoding apparatus shown in FIG. 6;

FIG. 8 is a block diagram showing the arrangement of a data transmission system according to a third embodiment;

FIG. 9 is a view for explaining the operation of the decoding apparatus shown in FIG. 8;

FIG. 10 is a view for explaining the operation of the decoding apparatus shown in FIG. 8; and

FIG. 11 is a flowchart for explaining the operation of the decoding apparatus shown in FIG. 8.

### DETAILED DESCRIPTION OF THE INVENTION

An embodiment of the present invention will be described below with reference to the views of the accompanying drawing.

### First Embodiment

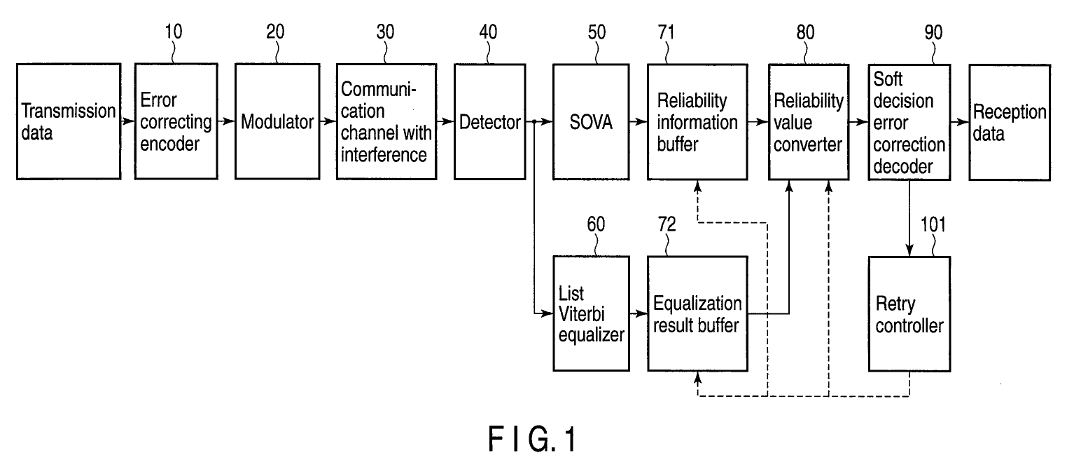

The first embodiment shown in FIG. 1 will exemplify a case in which the present invention is applied to a GSM (Global System for Mobile communication).

A data transmitting-side apparatus (encoding apparatus) includes an error correcting encoder 10 and a modulator 20.

The error correcting encoder 10 generates an error correcting code (ECC) on the basis of a predetermined number of bit strings (to be referred to as a bit sequence hereinafter), and outputs the generated error correcting code as one transmission data.

The modulator 20 modulates a carrier wave by using the transmission data output from the error correcting encoder 10, up-converts the carrier wave into a radio frequency, and transmits the resultant data to a data receiving-side apparatus (decoding apparatus).

In this manner, the above transmission data is wirelessly transmitted and received by the receiving-side apparatus via a communication channel 30 with interference. The communication channel 30 is a communication channel with interference which satisfies a Markov process. For this reason, inter-symbol interference occurs in a transmission signal. That is, the signal waveform received by the receiving-side apparatus is a waveform in which each symbol interferes with several symbols located before and after it. It is therefore necessary to equalize the received signal waveform by using a Viterbi equalizer or the like.

The data receiving-side apparatus includes a detector 40, a SOVA (Soft Output Viterbi Algorithm) equalizer 50, a list Viterbi equalizer 60, a reliability information buffer 71, an equalization result buffer 72, a reliability value converter 80, a soft decision error correction decoder 90, and a retry controller 101. Assume that in the following description, decoding processing is performed for each bit sequence.

The detector 40 performs detection by down-converting a radio signal received via the communication channel 30. In this case, an output from the detector 40 is the probability or logarithmic likelihood at which a transmission signal from the modulator 20 is received at an ideal signal point defined in a communication channel accompanying the above Markov process.

The SOVA equalizer 50 equalizes the detection result obtained by the detector 40, and obtains maximum likelihood sequence data by performing hard decision for each bit of the above bit sequence by maximum likelihood sequence estimation and reliability value data indicating the reliability of decision on each bit constituting the maximum likelihood sequence data. The SOVA equalizer 50 then outputs the respective data. The reliability information buffer 71 buffers the reliability value data obtained in this manner for subsequent processing. Note that the reliability information buffer 71 outputs the buffered reliability value data to the reliability value converter 80 in accordance with an instruction from the retry controller 101.

In accordance with an instruction from the retry controller 101, the list Viterbi equalizer 60 obtains a plurality of equalization candidates of the above bit sequence by performing hard decision on the above bit sequence by list Viterbi equalization on the basis of the detection result obtained by the detector 40. In the following description, a plurality of candidate strings obtained concerning the above bit string will be referred to as a candidate group, and will be respectively referred to as the first-order candidate string, the second-order candidate string, . . . , Nth-order candidate string (N is two or more) in descending order of reliability. The equalization result buffer 72 buffers the candidate group obtained in this manner for subsequent processing. Note that the equalization result buffer 72 outputs one candidate string of the buffered candidate group to the reliability value converter 80, based on a priority order, in accordance with an instruction from the retry controller 101.

In accordance with an instruction from the retry controller 101, the reliability value converter 80 converts the reliability value data from the SOVA equalizer 50 on the basis of the candidate strings obtained by the list Viterbi equalizer 60, and outputs the converted reliability value data to the soft decision error correction decoder 90.

More specifically, when the reliability value data of a given bit sequence obtained from the SOVA equalizer 50 (reliability information buffer 71) is output to the soft decision error correction decoder 90 for the first time, the reliability value converter 80 outputs the above reliability value data to the soft decision error correction decoder 90 without converting it.

When the reliability value data of the same bit sequence is to be output to the soft decision error correction decoder 90 again (in the case of retry) in accordance with an instruction from the retry controller 101, the reliability value converter 80 converts the above reliability value data on the basis of the first-order candidate string of the candidate strings buffered in the equalization result buffer 72, and outputs the converted reliability value data to the soft decision error correction decoder 90. Subsequently, when a retry instruction is output from the retry controller 101, reliability value data is converted and output on the basis of a subsequent-order candidate string. Note that the first-order candidate string may be discarded, and the second- and subsequent-order candidate strings may be sequentially used.

Conversion of a maximum likelihood sequence by the reliability value converter 80 will be described in detail below. In the following description, the reliability value data obtained by the SOVA equalizer 50 is the value obtained by soft decision on each bit. If this value is a logarithmic likelihood ratio, its absolute value indicates the degree of reliability, and the positive/negative sign indicates “1” or “0” of an information bit. The candidate string obtained by the list Viterbi equalizer 60 is a value obtained by the hard decision of deciding “1” or “0” for each bit. The code of the reliability value of each bit indicated by reliability value data is converted into a sign corresponding to a corresponding code of the candidate string.

When the reliability value data of each bit obtained by the SOVA equalizer 50 is to be expressed by a logarithmic likelihood ratio, a reliability value L[iₜ] of each bit can be expressed by mathematical expression (1) given below.

$$L [ {i}_{t} ] = log \frac{P [ {i}_{t} = 0 \vert {r}_{t} ]}{P [ {i}_{t} = 1 \vert {r}_{t} ]} = sign ( {i}_{t} ) \times \vert Λ [ {i}_{t} ] \vert = ( 1 - 2 {i}_{t} ) \times \vert Λ [ {i}_{t} ] \vert \\ {i}_{t} = 0 , 1 \\ sign ( {i}_{t} ) = \{ \begin{matrix}- 1 , & ( {i}_{t} = 1 ) \\ + 1 , & ( {i}_{t} = 0 )\end{matrix} \qquad ( 1 )$$

where iₜ is a hard decision bit label at time t which is obtained by maximum likelihood sequence estimation, and Λ[iₜ] is reliability information given by a logarithmic likelihood ratio for each bit iₜ which is obtained by maximum likelihood sequence estimation by the SOVA equalizer 50.

According to mathematical expression (1), when reliability value data is to be expressed by a logarithmic likelihood ratio, the reliability value obtained by the SOVA equalizer 50 can be considered by dividing it into its absolute value and the sign “+” or “−” determined by a hard-decision bit label. That is, changing the sign of the logarithmic likelihood ratio of the respective bits can provide logarithmic likelihood ratios corresponding to different bit labels without contradiction.

According to this principle, if the code of the logarithmic likelihood ratio obtained by the SOVA equalizer 50 is converted in accordance with a candidate string as a hard decision equalization result obtained by list Viterbi equalization by the list Viterbi equalizer 60 according to mathematical expression (20), the reliability value L[iₜ] can be added to each candidate string obtained by the list Viterbi equalizer 60.

L[iₜⁿ]=sign(iₜⁿ)×|Λ[iₜ¹]|=(1−2iₜⁿ)×|Λ[iₜ¹]| (2)

where iₜⁿ is the bit label of a candidate string with the nth highest probability at time t which is obtained by the list Viterbi equalizer 60, and iₜ¹ is the bit label at time t which is contained in the maximum likelihood sequence. When a probability value is to be applied to the operation of mathematical expression (2), instead of a logarithmic likelihood ratio, the values of P[iₜ=0|rₜ] and P[iₜ=1|rₜ] are replaced in accordance with the second- and subsequent-order candidate strings.

The soft decision error correction decoder 90 performs decoding processing by soft decision such as LDPC (Low Density Parity Check), and obtains a bit sequence by performing error correction decoding based on the reliability value data output from the reliability value converter 80. The soft decision error correction decoder 90 performs this error correction decoding by using the error correcting code (ECC) added on the transmitting side, and determines whether a normal bit sequence without error has been decoded.

If the above normal bit sequence is decoded, the decoded bit sequence is output as reception data. In addition, the retry controller 101 is notified of information indicating that the normal decoding result has been obtained. If a normal decoding result has not been obtained, the retry controller 101 is notified of the corresponding information.

Upon receiving a notification indicating that a normal decoding result has been obtained from the soft decision error correction decoder 90, the retry controller 101 refreshes the data buffered in the reliability information buffer 71 and the equalization result buffer 72 to prepare for the decoding of the next bit sequence. Upon receiving a notification indicating that a normal decoding result has not been obtained from the soft decision error correction decoder 90, the retry controller 101 instructs the reliability information buffer 71 to output buffered reliability value data again and also instructs the equalization result buffer 72 to output a candidate of the highest order which has not been output. In accordance with these instructions, the retry controller 101 causes the reliability value converter 80 to convert the reliability value data, which has been output again, on the basis of the above candidate string.

As described above, the decoding apparatus having the above arrangement includes the SOVA equalizer 50 which obtains reliability value data indicting the reliability of each bit of maximum likelihood sequence data and the list Viterbi equalizer 60 which obtains a plurality of candidate strings indicating a candidate of the bit sequence. The reliability value converter 80 repeatedly converts the above reliability value data on the basis of the above candidate strings, as needed, thereby allowing the soft decision error correction decoder 90 to decode a desired bit sequence.

The decoding apparatus having the above arrangement therefore can efficiently perform Viterbi equalization processing in spite of using list Viterbi equalization and the error correction scheme requiring soft-valued reliability information.

In the strict sense, when the logarithmic likelihood ratio for the maximum likelihood candidate obtained by the SOVA equalizer 50, is directly provided as reliability information to the second- or subsequent-order candidate string which is not the first-order candidate string obtained by the list Viterbi equalizer 60, the logarithmic likelihood ratio is not an accurate reliability value. However, in decoding processing which requires reliability values, executing retry processing using a plurality of candidate strings obtained by the list Viterbi equalizer 60 can perform equalization and decoding processing at high speed at the time of a retry because likelihood values can be provided most easily.

The above embodiment has exemplified the communication system based on the GSM scheme. However, the present invention is not limited to this. For example, as a data transmitting-side apparatus, a data reader such as an HDD (Hard Disk Drive) or an optical disk drive can be assumed to be used. In this case, data is recorded on a recording medium such as an HDD or an optical disk by predetermined modulation processing after the data is error-correction encoded. For example, a consumer appliance such as a DVD (Digital Versatile Disc) recorder or an HDD recorder can be assumed to be used, and a data receiving-side apparatus can be mounted in the same appliance. This also applies to the second and third embodiments to be described later.

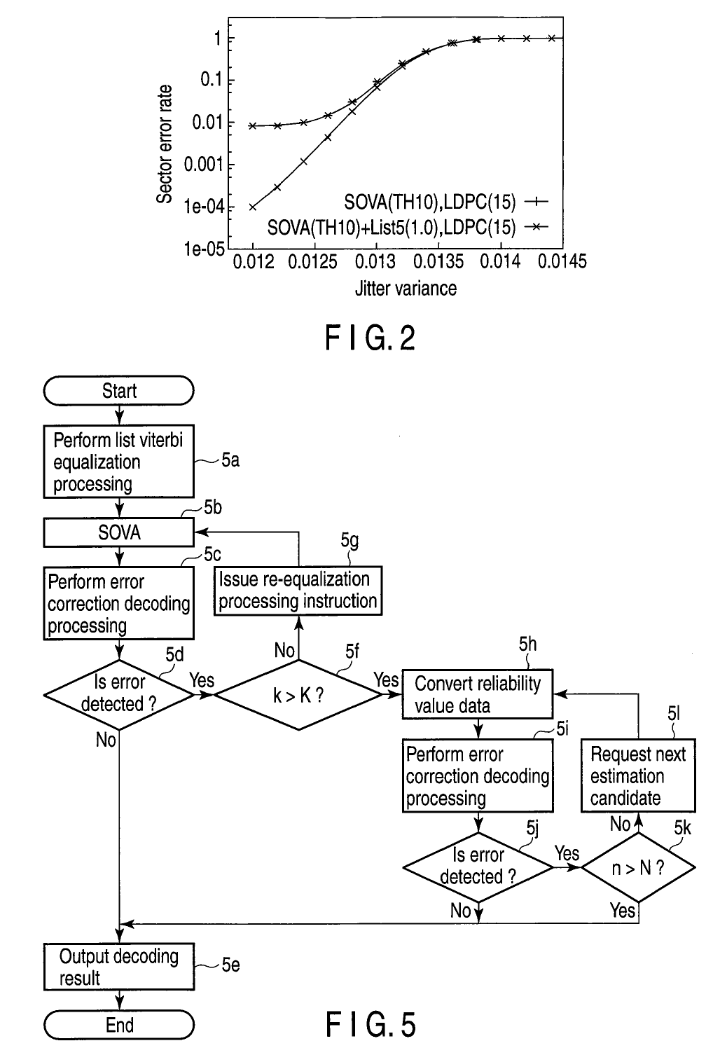

FIG. 2 shows an error rate characteristic obtained by simulating a case in which when magnetically recorded data is read out from a medium, the readout data receives interference in a transmission channel. In this case, as a transmission channel for magnetically recorded data which has been read out, PR(560-1) as a PR communication channel constituted by a modulator, a recording medium, and an FIR (Finite Impulse Response) equalizer is assumed to be used. In addition, as an error correcting code generated by the error correcting encoder 10 and the soft decision error correction decoder 90, a QC-LDPC (Quasi Cyclic-LDPC) code having a code length of 36,500 bits is used. Assume that the number of estimation candidates in hard decision in the list Viterbi equalizer 60 is N=5, and the retry controller 101 performs decoding retry processing five times at maximum. The LDPC decoding algorithm in the soft decision error correction decoder 90 is the min-sum algorithm, which is designed to perform iterative processing 15 times at maximum.

Referring to FIG. 2, SOVA(TH10) indicates a frame error rate characteristic obtained by using the reliability information of maximum likelihood sequence data obtained by the general SOVA, and SOVA+List5 indicates a frame error rate characteristic obtained by the present invention under the above conditions. This result reveals that the present invention can improve the frame error rate in two orders of magnitude compared with decoding processing by the general SOVA without performing retransmission or re-reading operation at the time of detection of an error.

That is, the present invention can improve the error rate characteristic while maintaining the throughput in one data transmission cycle by performing simple retry processing alone, i.e., operating the positive/negative sign of reliability information corresponding to the maximum likelihood candidate obtained by SOVA, on the basis of a plurality of hard decision results by list Viterbi equalization, without performing retransmission of transmission data or re-reading of playback data.

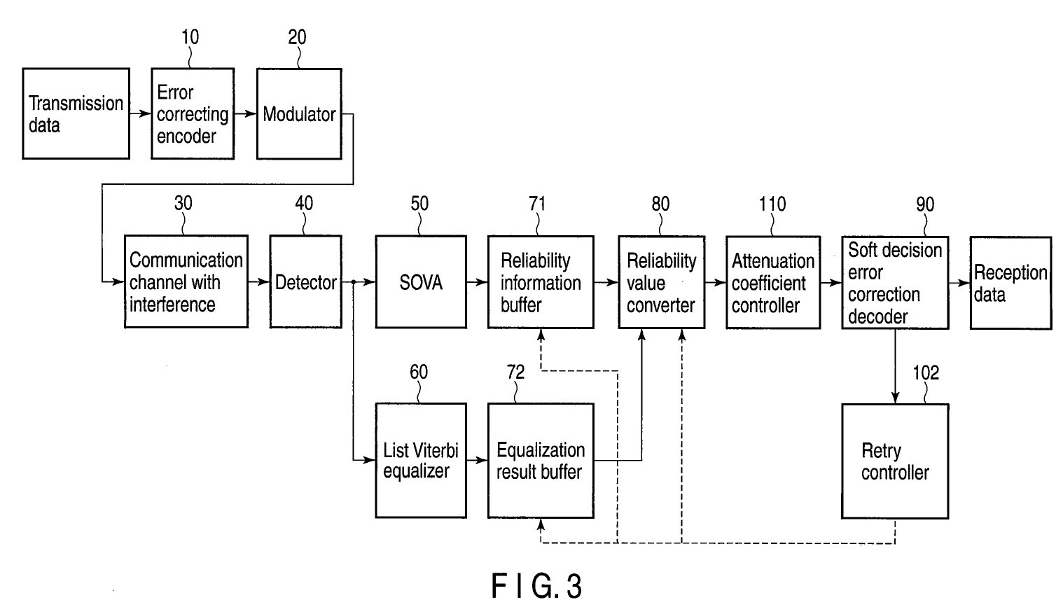

Note that the decoding apparatus having the above arrangement can be modified as shown in FIG. 3. That is, an attenuation coefficient controller 110 is newly provided between the reliability value converter 80 and the soft decision error correction decoder 90, and a retry controller 102 is provided instead of the retry controller 101. In addition to the control function of the retry controller 101, the retry controller 102 has a control function of increasing the attenuation coefficient used by the attenuation coefficient controller 110 in accordance with the order of a candidate string used by the reliability value converter 80, when the soft decision error correction decoder 90 cannot normally perform decoding. The attenuation coefficient controller 110 attenuates the magnitude of the reliability value converted by the reliability value converter 80 by using the attenuation coefficient designated by the retry controller 102.

In this case, in particular, it suffices to apply an attenuation coefficient to only a bit having a bit label different from that of the previous equalization candidate or apply an attenuation coefficient to overall reliability values as the order of a decoding candidate increases due to retry processing.

According to the decoding apparatus having the above arrangement, as retry processing is repeated, the order of a candidate string used by the reliability value converter 80 increases. That is, as the reliability of a candidate string decreases, the magnitude of the reliability value converted by the reliability value converter 80 using the candidate string is attenuated. For this reason, properly evaluated reliability value data is input to the soft decision error correction decoder 90. This can prevent an over-evaluated reliability value from being used and suppress the correction of an ECC into an erroneous codeword.

It is obvious from the maximum likelihood estimation principle that, of the N candidate strings obtained by the list Viterbi equalizer 60, the second- and subsequent-order estimation candidate strings are lower in likelihood than the maximum likelihood candidate (first-order candidate string). For this reason, an attenuation coefficient a is applied to the reliability value L[iₜⁿ], as indicated by mathematical expression (3), for the second- and subsequent-order candidate strings obtained by the list Viterbi equalizer 60. Note that the retry controller 102 sets an attenuation coefficient in accordance with a bit label.

$$L [ {i}_{t}^{n} ] = α ( {i}_{t}^{n} , {i}_{t}^{1} ) \times sign ( {i}_{t}^{n} ) \times \vert Λ [ {i}_{t}^{1} ] \vert \\ α ( {i}_{t}^{n} , {i}_{t}^{1} ) = \{ \begin{matrix}1 , & ( {i}_{t}^{n} = {i}_{t}^{1} ) \\ 0 \leq α < 1 , & ( {i}_{t}^{n} \neq {i}_{t}^{1} )\end{matrix} \qquad ( 3 )$$

In this case, the value of the attenuation coefficient α can be a predetermined constant or a coefficient obtained by another element. For example, it suffices to use a coefficient determined on the basis of the reliability difference obtained from the difference between the cumulative metric value based on the first-order estimation candidate obtained by the list Viterbi equalizer 60 and the cumulative metric value based on second- or subsequent-order estimation candidate.

As the difference between the cumulative metric value based on the first-order candidate string and the cumulative metric value based on each of the second- and subsequent-order estimation candidates increases, the reliability of the second- or subsequent-order candidate string decreases. Note that a cumulative metric value is the sum of reliability values obtained from the detector used to estimate a maximum likelihood candidate in Viterbi equalization. That is, a sequence with the highest reliability value, which is a maximum likelihood estimation candidate, is obtained as an equalization result by accumulating reliability values in Viterbi equalization.

For the same reason, the second- or subsequent-order estimation candidate obtained by list Viterbi equalization is a sequence whose cumulative metric is the second largest. Likewise, a sequence with the Nth largest cumulative metric is output as an Nth-order estimation candidate. That is, when the cumulative metric value of the Nth-order estimation candidate is compared with the cumulative metric value of the first-order estimation candidate and the difference between them is large, the reliability of the Nth-order candidate is lower than that of the maximum likelihood estimation candidate. If the cumulative metric difference is small, the reliability of the Nth-order estimation candidate can be regarded as being close to the reliability of the maximum likelihood estimation candidate.

### Second Embodiment

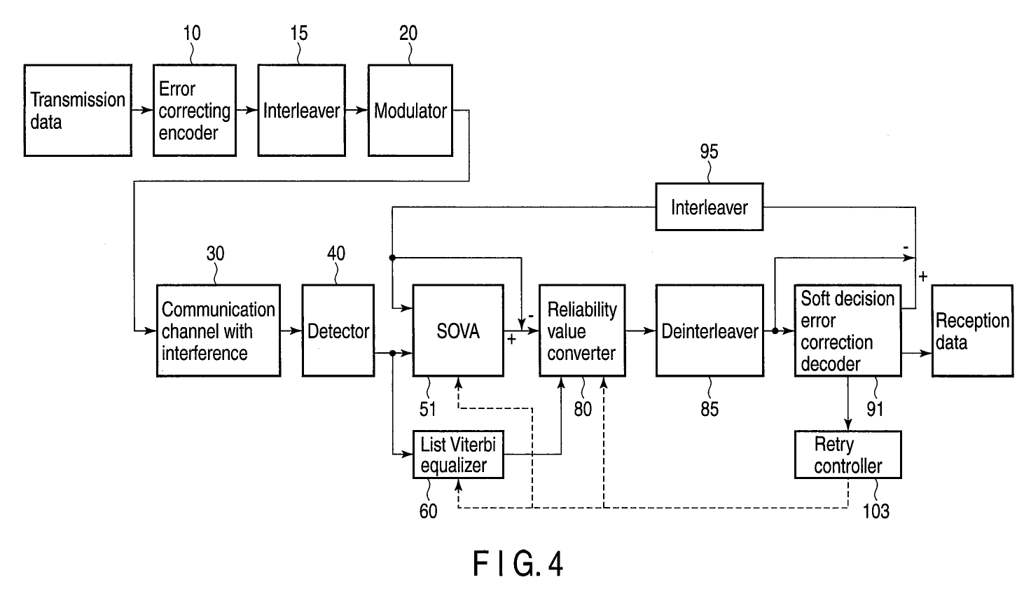

The second embodiment shown in FIG. 4 will exemplify a case in which the present invention is applied to a GSM (Global System for Mobile communication).

A data transmitting-side apparatus (encoding apparatus) includes an error correcting encoder 10, an interleaver 15, and a modulator 20.

The error correcting encoder 10 generates an error correcting code on the basis of a predetermined number of bit strings (to be referred to as a bit sequence hereinafter), and outputs the generated error correcting code (ECC) as one transmission data.

The interleaver 15 interleaves the above transmission data.

The modulator 20 modulates a carrier wave by using the transmission data interleaved by the interleaver 15, up-converts the carrier wave into a radio frequency, and transmits the resultant data to a data receiving-side apparatus.

In this manner, the above transmission data is radio-transmitted and received by a receiving-side apparatus (decoding apparatus) via a communication channel 30 with interference. The communication channel 30 is a communication channel with interference which satisfies a Markov process. For this reason, inter-symbol interference occurs in a transmission signal. That is, the signal waveform received by the receiving-side apparatus is a waveform in which each symbol interferes with several symbols located before and after it. It is therefore necessary to equalize the received signal waveform by using a Viterbi equalizer or the like.

The data receiving-side apparatus includes a detector 40, a SOVA (Soft Output Viterbi Algorithm) equalizer 51, a list Viterbi equalizer 60, a reliability value converter 80, a deinterleaver 85, a soft decision error correction decoder 91, an interleaver 95, and a retry controller 103. Assume that in the following description, decoding processing is performed for each bit sequence.

The detector 40 performs detection by down-converting a radio signal received via the communication channel 30.

In accordance with an instruction from the retry controller 103, the SOVA equalizer 51 obtains maximum likelihood sequence data by hard decision on each bit of the above bit sequence by maximum likelihood estimation, on the basis of the detection result obtained by the detector 40 and an extrinsic value, and reliability value data indicating the reliability of decision on each bit of the maximum likelihood sequence data. The SOVA equalizer 51 then outputs the respective data.

More specifically, at an early stage of operation, in accordance with an instruction from the retry controller 103, the SOVA equalizer 51 obtains maximum likelihood sequence data upon hard decision by maximum likelihood sequence estimation for each bit of the above bit sequence and reliability value data indicating the reliability of each bit of the maximum likelihood sequence data, and outputs the respective data.

Note that at an early stage of operation, the interleaver 95 (to be described later) outputs “0” as an extrinsic value. As a consequence, the reliability value data obtained by the SOVA equalizer 51 is output to the reliability value converter 80 without any change. In this case, an early stage of operation indicates the first decoding processing for a given bit string but does not indicate an early stage of the overall decoding processing. This applies to the following description.

When a re-equalization instruction is issued from the retry controller 103, the immediately precedingly obtained reliability value data is re-equalized by using the extrinsic value supplied from the interleaver 95 and the detection result obtained by the detector 40. The above extrinsic value is subtracted from the reliability value data obtained by such re-equalization for each corresponding bit, and the resultant data is output to the reliability value converter 80. Note that re-equalization is performed K times at maximum in accordance with an instruction from the retry controller 103.

In accordance with an instruction from the retry controller 103, the list Viterbi equalizer 60 obtains a plurality of candidate strings indicating a candidate of the above bit sequence by performing hard decision on the above bit sequence by list Viterbi equalization on the basis of the detection result obtained by the detector 40. In the following description, a plurality of candidate strings obtained concerning the above bit string will be referred to as a candidate group, and will be respectively referred to as the first-order candidate string, the second-order candidate string, . . . , Nth-order candidate string (N is two or more) in descending order of reliability.

In accordance with an instruction from the retry controller 103, the reliability value converter 80 converts the reliability value data, from which the output (extrinsic value) from the interleaver 95 is subtracted, on the basis of the candidate strings obtained by the list Viterbi equalizer 60, and outputs the converted reliability value data to the deinterleaver 85.

More specifically, when the reliability value data of a given bit sequence obtained from the SOVA equalizer 51 (reliability information buffer 71) is output to the deinterleaver 85 for the first time, or immediately after re-equalized reliability value data is output from the SOVA equalizer 51, the reliability value converter 80 outputs the input reliability value data to the deinterleaver 85 without converting it.

When the reliability value data of the same bit sequence obtained by re-equalization is to be output to the deinterleaver 85 (in the case of retry) in accordance with an instruction from the retry controller 103, the reliability value converter 80 converts the above reliability value data on the basis of the first-order candidate string of the candidate strings obtained by the list Viterbi equalizer 60, and outputs the converted reliability value data to the deinterleaver 85. Subsequently, when a retry instruction is output from the retry controller 103, the same reliability value data is converted and output on the basis of a subsequent-order candidate string. Note that the first-order candidate string may be discarded, and the second- and subsequent-order candidate strings may be used.

Since the detailed principle of the conversion of a maximum likelihood sequence performed by the reliability value converter 80 has been described in the first embodiment, a description of the principle will be omitted.

The deinterleaver 85 corresponds to the interleaver 15 of the data transmitting-side apparatus, and deinterleaves the reliability value data output from the reliability value converter 80.

The soft decision error correction decoder 91 performs decoding processing by soft decision such as LDPC (Low Density Parity Check), and obtains a bit sequence by performing error correction decoding based on the reliability value data deinterleaved by the deinterleaver 85. In this error correction decoding, the error correcting code (ECC) added on the transmitting side is used, and a probability value indicating the reliability of the decoding result is obtained. After the error correction decoding processing, the soft decision error correction decoder 91 determines whether a normal bit sequence without error has been decoded.

If the above normal bit sequence is decoded, the decoded bit sequence is output as reception data. In addition, the retry controller 103 is notified of information indicating that the normal decoding result has been obtained.

If a normal decoding result has not been obtained, the soft decision error correction decoder 91 notifies the retry controller 103 of the corresponding information, and also outputs the above probability value obtained in the decoding process. With this operation, the reliability value data deinterleaved by the deinterleaver 85 is subtracted from the above probability value for each corresponding bit. This subtraction result is output as a posterior probability value to the interleaver 95. The interleaver 95 interleaves the input data and outputs the resultant data as an extrinsic value.

Upon receiving, from the soft decision error correction decoder 90, a notification indicating that a normal decoding result has been obtained, the retry controller 103 prepares for the decoding of the next bit sequence. In contrast, assume that the retry controller 103 receives, from the soft decision error correction decoder 90, a notification indicating that a normal decoding result has not been obtained, and the decoding operation is not based on the reliability value data converted on the basis of the candidate string obtained by the list Viterbi equalizer 60. In this case, the retry controller 103 instructs the SOVA equalizer 51 to perform re-equalization. This re-equalization and accompanying decoding are performed K times at maximum.

If the soft decision error correction decoder 90 obtains a normal decoding result by decoding using the reliability value data obtained by re-equalization, the retry controller 103 prepares for the decoding of the next bit sequence. Upon receiving, from the soft decision error correction decoder 90, a notification indicating that a normal decoding result has not been obtained even after re-equalization and accompanying decoding performed K times, the retry controller 103 instructs the reliability value converter 80 to convert the reliability value data obtained by re-equalization on the basis of the above candidate string. With this operation, the soft decision error correction decoder 90 is controlled to perform decoding by using the reliability value data converted on the basis of the above candidate string.

The operation of the receiving-side apparatus having the above arrangement will be described next with reference to FIG. 5. The processing shown in FIG. 5 is executed for each bit sequence to be decoded.

First of all, in step 5a, in accordance with an instruction from the retry controller 103, the list Viterbi equalizer 60 obtains a plurality of candidate strings indicating a candidate of the above bit sequence by performing hard decision by list Viterbi equalization for the bit sequence on the basis of the detection result obtained by the detector 40. The process then shifts to step 5b. Note that at an early stage of operation, steps 5a and 5b may be concurrently performed.

In step 5b, in accordance with an instruction from the retry controller 103, the SOVA equalizer 51 obtains maximum likelihood sequence data by hard decision on each bit of the above bit sequence as a decoding target by maximum likelihood sequence estimation and reliability value data indicating the reliability of each bit of the maximum likelihood sequence data, on the basis of the detection result obtained by the detector 40 and an extrinsic value (“0” at an early stage of operation). The process then shifts to step 5c. The reliability value data obtained in this manner passes through the reliability value converter 80, and is deinterleaved by the deinterleaver 85. The resultant data is then output to the soft decision error correction decoder 91.

In step 5c, the soft decision error correction decoder 91 obtains a bit sequence by performing error correction decoding based on the reliability value data deinterleaved by the deinterleaver 85. The process then shifts to step 5d. Note that in decoding operation, a probability value indicating the reliability of a decoding result is obtained.

In step 5d, the soft decision error correction decoder 91 notifies the retry controller 103 as to whether a normal decoding result without error has been obtained. If a normal decoding result has not been obtained, i.e., an error has been detected from the decoding result, the process shifts to step 5f. If no error has been detected, the process shifts to step 5e.

In step 5e, the soft decision error correction decoder 91 outputs the bit sequence obtained by decoding to the data processing unit (not shown) on the subsequent stage. The processing is then terminated. The apparatus then starts processing the next bit sequence again.

In step 5f, the retry controller 103 increments a parameter k indicating the number of times of execution of re-equalization, and determines whether the value k exceeds a threshold K. If the parameter k does not exceed the threshold K, the process shifts to step 5g. If the parameter k exceeds the threshold K, the process shifts to step 5h.

In step 5g, the retry controller 103 instructs the SOVA equalizer 51 to perform re-equalization. The process then shifts to step 5b. In this case, the reliability value data used for decoding in step 5c is subtracted from the probability value output from the soft decision error correction decoder 91 for each corresponding bit. The interleaver 95 interleaves the subtraction result, and supplies the resultant data as an extrinsic value to the SOVA equalizer 51. With this operation, in step 5b, the SOVA equalizer 51 performs re-equalization by using the above extrinsic value and the detection result obtained by the detector 40, and obtains new reliability value data.

In step 5h, the reliability value converter 80 selects an upper candidate string (nth candidate), of the candidate strings obtained by the list Viterbi equalizer 60, which has not been selected in accordance with an instruction from the retry controller 103, and converts the reliability value data, from which the output (extrinsic value) from the interleaver 95 is subtracted, on the basis of the selected candidate string. The reliability value converter 80 then outputs the converted reliability value data to the deinterleaver 85. The process then shifts to step 5i.

In step 5i, the soft decision error correction decoder 91 obtains a bit sequence by performing error correction decoding based on the reliability value data converted by the reliability value converter 80. The process then shifts to step 5j. Note that the probability value obtained in this decoding is not output because the value obtained after re-equalization is performed up to the maximum number of times (k).

In step 5j, the soft decision error correction decoder 91 notifies the retry controller 103 as to whether a normal decoding result without error has been obtained. If a normal decoding result has not been obtained, i.e., an error has been detected from the decoding result, the process shifts to step 5k. If no error has been detected from the decoding result, the process shifts to step 5e.

In step 5k, the retry controller 103 increments a parameter n indicating the number of times of conversion executed by the retry controller 103, and determines whether the value exceeds a threshold N. If the parameter n does not exceed the threshold N, the process shifts to step 5l. If the parameter n exceeds the threshold N, the process shifts to step 5e. In this case, in step 5e, a decoding result containing an error is output. In subsequent processing, therefore, a retransmission request is issued to the transmitting side.

In step 5l, the retry controller 103 instructs the reliability value converter 80 to perform conversion based on the nth candidate string, of the candidate strings obtained by the list Viterbi equalizer 60, which has not been selected. The process then shifts to step 5h. With this operation, in step 5h, the reliability value converter 80 converts the reliability value data on the basis of the nth candidate string.

As described above, the decoding apparatus having the above arrangement includes the SOVA equalizer 51 which obtains reliability value data indicting the reliability of each bit of the maximum likelihood sequence data of a bit sequence and the list Viterbi equalizer 60 which obtains a plurality of candidate strings indicating a candidate of the bit sequence. If normal data cannot be obtained by decoding based on the above reliability value data, the apparatus causes the SOVA equalizer 51 to perform re-equalization by using the probability value obtained in decoding. If normal data cannot be obtained even by performing decoding based on the reliability value data obtained by re-equalization, the reliability value converter 80 repeatedly converts the reliability value data obtained by re-equalization on the basis of the above candidate string, as needed, thereby allowing the soft decision error correction decoder 90 to decode a desired bit sequence.

The decoding apparatus having the above arrangement therefore can efficiently perform Viterbi equalization processing in spite of using list Viterbi equalization and the error correction scheme requiring soft-valued reliability information.

In the second embodiment, if a desired bit string cannot be obtained by decoding, the SOVA equalizer 51 performs decoding upon re-equalization, and the reliability value data obtained by the SOVA equalizer 51 is further converted by using the candidate string obtained by the list Viterbi equalizer 60, as needed. Instead of this processing, the order of execution of re-equalization and conversion processing using a candidate string can be changed as follows. First of all, retry processing is repeated, as needed, so as to convert the reliability value data obtained by the SOVA equalizer 51 by using the candidate string obtained by the list Viterbi equalizer 60. Thereafter, the SOVA equalizer 51 performs re-equalization, as needed. In this case, a retry is performed to perform re-equalization from the probability value obtained by decoding based on the finally converted reliability value data.

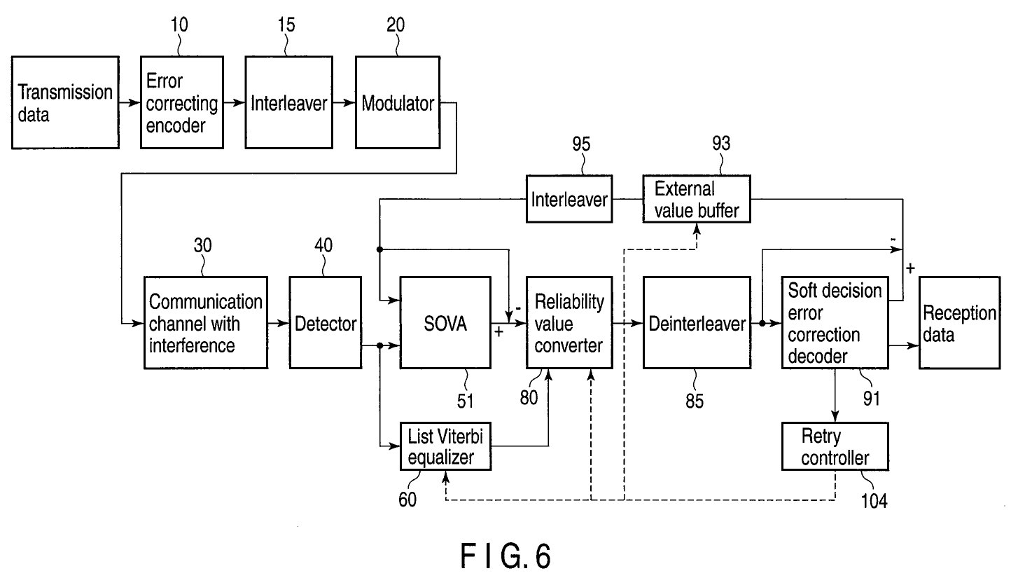

In contrast to this, with the arrangement shown in FIG. 6, the probability value obtained by decoding based on the reliability value data obtained by the SOVA equalizer 51 can be buffered in an extrinsic value buffer 93 at an early stage of operation, and the SOVA equalizer 51 can perform re-equalization on the basis of the probability value buffered in the extrinsic value buffer 93.

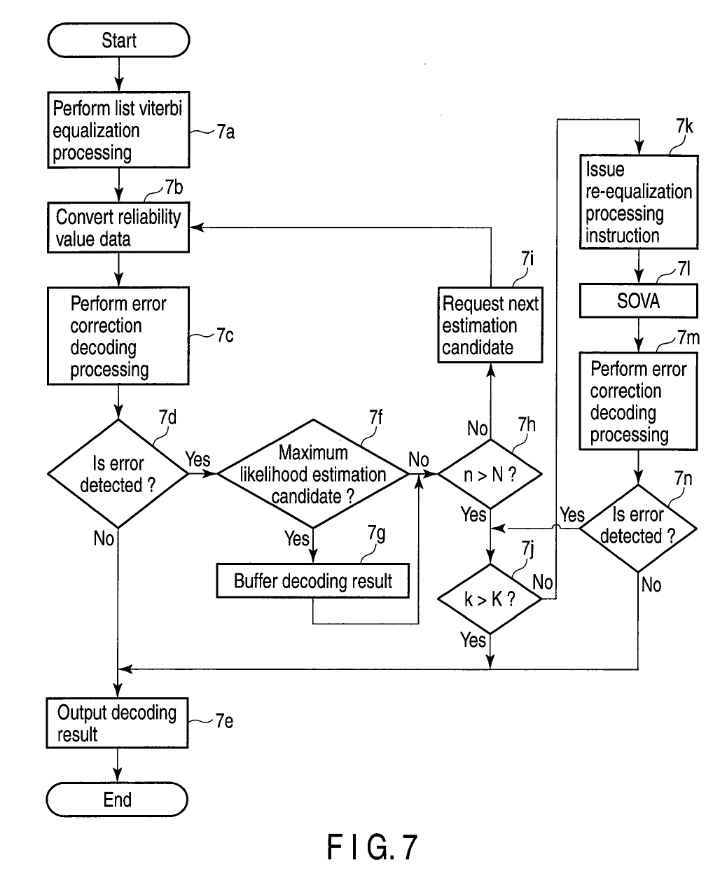

The operation of the receiving-side apparatus having the arrangement shown in FIG. 6 will be described with reference to FIG. 7. The processing shown in FIG. 7 is executed for each bit sequence to be decoded.

First of all, in step 7a, concurrently with the operation of the SOVA equalizer 51, the list Viterbi equalizer 60 performs hard decision by list Viterbi equalization for the bit sequence to obtain a plurality of candidate strings indicating a candidate of the bit sequence, on the basis of the detection result obtained by the detector 40, in accordance with an instruction from a retry controller 104. The process then shifts to step 7b.

In step 7b, the reliability value converter 80 selects an upper candidate string (nth candidate), of the candidate strings obtained by the list Viterbi equalizer 60, which has not been selected in accordance with an instruction from the retry controller 104, and converts the reliability value data, from which the output (extrinsic value: “0” at an early stage of operation) from the interleaver 95 is subtracted, on the basis of the selected candidate string. The reliability value converter 80 then outputs the converted reliability value data to the deinterleaver 85. The process then shifts to step 7c. Note that n=0 is set at an early stage of operation, and the reliability value data obtained by the SOVA equalizer 51 is output without any change when n is “0”.

In step 7c, the soft decision error correction decoder 91 obtains a bit sequence by performing error correction decoding based on the reliability value data converted by the reliability value converter 80 and deinterleaved by the deinterleaver 85. The process then shifts to step 7d. Note that when this decoding operation is performed, a probability value indicating the reliability of a decoding result is obtained.

In step 7d, the soft decision error correction decoder 91 notifies the retry controller 104 as to whether a normal decoding result without error has been obtained. If a normal decoding result has not been obtained, i.e., an error has been detected from the decoding result, the process shifts to step 7f. If no error has been detected from the decoding result, the process shifts to step 7e.

In step 7e, the soft decision error correction decoder 91 outputs the bit sequence obtained by decoding to the data processing unit (not shown) on the subsequent stage. This processing is then terminated, and processing for the next bit sequence is started again.

In step 7f, the retry controller 104 determines whether the decoding processing performed in step 7c is for reliability value data corresponding to the maximum likelihood sequence data obtained by the SOVA equalizer 51. That is, the retry controller 104 determines whether the above data is reliability value data which has not been converted in step 7b. If this data is reliability value data corresponding to the maximum likelihood sequence data obtained by the SOVA equalizer 51, the process shifts to step 7g. If the data is the reliability value data converted in step 7b, the process shifts to step 7h.

In step 7g, the reliability value data used in decoding in step 7c is subtracted from the probability value output from the soft decision error correction decoder 91 for each corresponding bit, and the subtraction result is buffered as an extrinsic value in an extrinsic value buffer 93. The process then shifts to step 7h.

In step 7h, the retry controller 104 increments the parameter n indicating the number of times of conversion executed by the retry controller 104, and determines whether the value exceeds the threshold N. If the parameter n does not exceed the threshold N, the process shifts to step 7i. If the value exceeds the threshold N, the process shifts to step 7j.

In step 7i, the retry controller 104 instructs the reliability value converter 80 to perform conversion based on the nth candidate string, of the candidate strings obtained by the list Viterbi equalizer 60, which has not been selected. The process then shifts to step 7b. In step 7b, the reliability value converter 80 converts the reliability value data on the basis of the nth candidate string.

In step 7j, the retry controller 104 increments the parameter k indicating the number of times of re-equalization executed by the retry controller 104, and determines whether the value k exceeds the threshold K. If the parameter k does not exceed the threshold K, the process shifts to step 7k. If the parameter k exceeds the threshold K, the process shifts to step 7e. In this case, in step 7e, a result containing an error is output, and a retransmission request is issued to the transmitting side by the subsequent processing.

In step 7k, the retry controller 104 instructs the SOVA equalizer 51 to perform re-equalization. The process then shifts to step 7l.

In step 7l, in accordance with an instruction from the retry controller 104, the SOVA equalizer 51 obtains maximum likelihood sequence data by hard decision on each bit of the above bit sequence as a decoding target by maximum likelihood sequence estimation and reliability value data indicating the reliability of each bit of the maximum likelihood sequence data, on the basis of the detection result obtained by the detector 40 and the data obtained by interleaving the extrinsic value buffer in the extrinsic value buffer 93 by using the interleaver 95.

The reliability value data obtained in this manner passes through the reliability value converter 80, and is deinterleaved by the deinterleaver 85. The resultant data is then output to the soft decision error correction decoder 91.

In step 7m, the soft decision error correction decoder 91 obtains a bit sequence by performing error correction decoding based on the reliability value data deinterleaved by the deinterleaver 85. The process then shifts to step 7n. Note that the reliability value data used for decoding in step 7c is subtracted from the probability value obtained by this decoding operation for each corresponding bit. This subtraction result is buffered as an extrinsic value in the extrinsic value buffer 93.

In step 7n, the soft decision error correction decoder 91 notifies the retry controller 104 as to whether a normal decoding result without error has been obtained. If a normal decoding result has not been obtained, i.e., an error has been detected from the decoding result, the process shifts to step 7j. If no error has been detected, the process shifts to step 7e.

According to the above processing, since a probability value obtained by decoding based on reliability data with high reliability is used for re-equalization instead of a probability value obtained by decoding based on the reliability value data converted by the reliability value converter 80, a desired bit string can be easily obtained by decoding.

### Third Embodiment

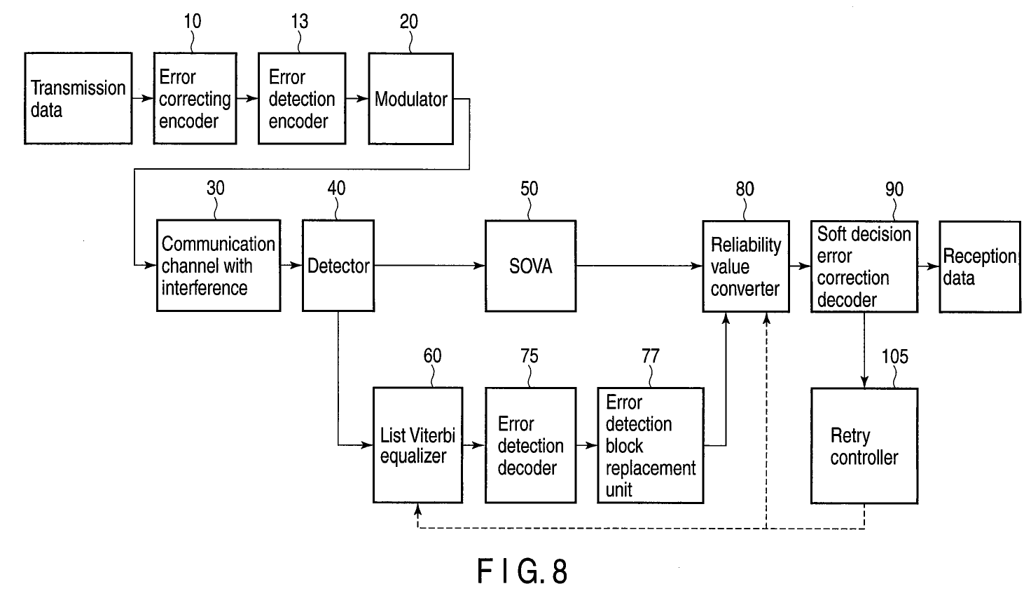

The third embodiment shown in FIG. 8 will exemplify a case in which the present invention is applied to a GSM (Global System for Mobile communication).

A data transmitting-side apparatus (encoding apparatus) includes an error correcting encoder 10, an error detection encoder 13, and a modulator 20.

The error correcting encoder 10 generates an error correcting code on the basis of a predetermined number of bit strings (to be referred to as a bit sequence hereinafter).

The error detection encoder 13 generates an error detection code on the basis of the above bit sequence to which an error correcting code is added by the error correcting encoder 10, and outputs the generated error detection code as one transmission data. Note that the error detection encoder 13 generates an error detection code for a unit bit string shorter than that in the error correcting encoder 10. For this purpose, the error detection encoder 13 divides a bit sequence to which an error correcting code is added into, for example, three bit strings, and generates an error detection code for each bit string.

The modulator 20 modulates a carrier wave by using the transmission data output from the error correcting encoder 10, up-converts the carrier wave into a radio frequency, and transmits the resultant data to a data receiving-side apparatus (decoding apparatus).

In this manner, the above transmission data is wirelessly transmitted and received by the receiving-side apparatus via a communication channel 30 with interference. The communication channel 30 is a communication channel with interference which satisfies a Markov process. For this reason, inter-symbol interference occurs in a transmission signal. That is, the signal waveform received by the receiving-side apparatus is a waveform in which each symbol interferes with several symbols located before and after it. It is therefore necessary to equalize the received signal waveform by using a Viterbi equalizer or the like.

The data receiving-side apparatus includes a detector 40, a SOVA (Soft Output Viterbi Algorithm) equalizer 50, a list Viterbi equalizer 60, an error detection decoder 75, an error detection block replacement unit 77, a reliability value converter 80, a soft decision error correction decoder 90, and a retry controller 105. Assume that in the following description, decoding processing is performed for each bit sequence.

The detector 40 performs detection by down-converting a radio signal received via the communication channel 30.

The SOVA equalizer 50 equalizes the detection result obtained by the detector 40, and obtains maximum likelihood sequence data obtained by hard decision on each bit of the above bit sequence by maximum likelihood sequence estimation and reliability value data indicating the reliability of decision on each bit constituting the maximum likelihood sequence data. The SOVA equalizer 50 then outputs the respective data. Note that the reliability value data obtained here is buffered in, for example, a buffer similar to the reliability information buffer 71 shown in FIG. 1.

In accordance with an instruction from the retry controller 105, the list Viterbi equalizer 60 obtains a plurality of candidate strings indicating a candidate of the above bit sequence by performing hard decision on the above bit sequence by list Viterbi equalization on the basis of the detection result obtained by the detector 40. In the following description, a plurality of candidate strings obtained for the above bit string will be referred to as a candidate group, and will be respectively referred to as the first-order candidate string, the second-order candidate string, . . . , Nth-order candidate string (N is two or more) in descending order of reliability.

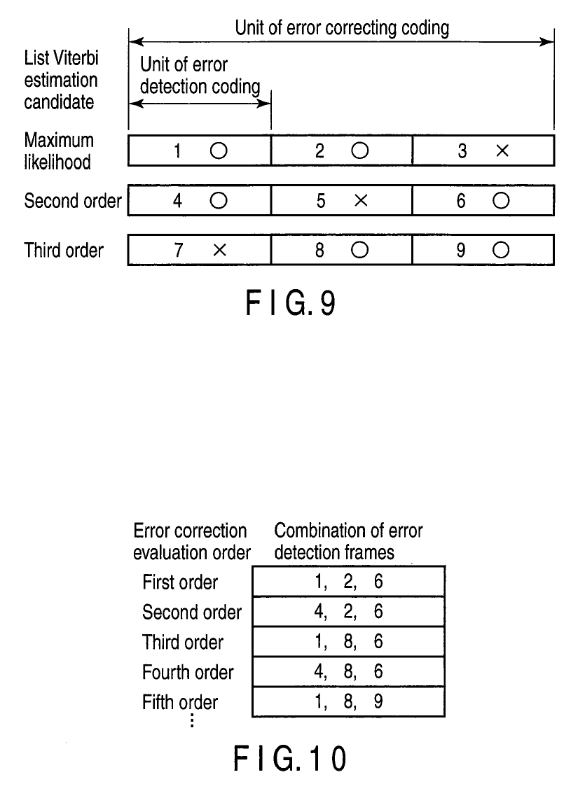

The error detection decoder 75 performs error detection decoding for each of a plurality of candidate strings obtained by the list Viterbi equalizer 60 to detect whether each candidate string contains an error. In this case, a candidate string corresponds to a bit sequence. However, since error detection decoding performed by the error detection decoder 75 corresponds to the error detection encoder 13, an error is detected for each bit string constituting the above bit sequence. FIG. 9 shows an example of this operation.

The error detection block replacement unit 77 divides a plurality of candidate strings obtained by the list Viterbi equalizer 60 into three bit strings (data blocks), and preferentially combines three bit strings without error on the basis of the detection result obtained by the error detection decoder 75, thereby performing replace processing to rearrange candidate strings.

If, for example, the error detection decoder 75 obtains the result shown in FIG. 9, the error detection block replacement unit 77 generates new candidate strings by replacing three bit strings constituting each candidate sting, as shown in FIG. 10. Note that the candidate strings obtained in this case are buffered in descending order of reliability in a buffer similar to the equalization result buffer 72 shown in FIG. 1.

In accordance with an instruction from the retry controller 105, the reliability value converter 80 converts the reliability value data obtained by the SOVA equalizer 50 on the basis of the candidate strings obtained by the error detection block replacement unit 77, and outputs the converted reliability value data to the soft decision error correction decoder 90.

More specifically, when the reliability value data of a given bit sequence obtained from the SOVA equalizer 50 (reliability information buffer 71) is output to the soft decision error correction decoder 90 for the first time, the reliability value converter 80 outputs the above reliability value data to the soft decision error correction decoder 90 without converting it.

When the reliability value data of the same bit sequence is to be output to the soft decision error correction decoder 90 again (in the case of retry) in accordance with an instruction from the retry controller 105, the reliability value converter 80 converts the above reliability value data on the basis of the first-order candidate string of the candidate strings buffered in an equalization result buffer 72, and outputs the converted reliability value data to the soft decision error correction decoder 90. Subsequently, when a retry instruction is output from the retry controller 105, the same reliability value data is converted and output on the basis of a subsequent-order candidate string. Note that the first-order candidate string may be discarded, and the second- and subsequent-order candidate strings may be used.

Since the detailed principle of the conversion of a maximum likelihood sequence by the reliability value converter 80 has been described in the first embodiment, a description of the principle will be omitted.

The soft decision error correction decoder 90 performs decoding processing by soft decision such as LDPC (Low Density Parity Check), and obtains a bit sequence by performing error correction decoding based on the reliability value data output from the reliability value converter 80. The soft decision error correcting decoder 90 performs this error correction decoding by using the error correcting code (ECC) added on the transmitting side, and determines whether a normal bit sequence without error has been decoded.

If the above normal bit sequence is decoded, the decoded bit sequence is output as reception data. In addition, the retry controller 105 is notified of information indicating that the normal decoding result has been obtained. If a normal decoding result has not been obtained, the retry controller 105 is notified of the corresponding information.

Upon receiving a notification indicating that a normal decoding result has been obtained from the soft decision error correction decoder 90, the retry controller 105 refreshes the data buffered in the reliability information buffer 71 and the equalization result buffer 72 to prepare for the decoding of the next bit sequence. Upon receiving a notification indicating that a normal decoding result has not been obtained from the soft decision error correction decoder 90, the retry controller 105 instructs the reliability information buffer 71 to output buffered reliability value data again and also instructs the equalization result buffer 72 to output a candidate string having the maximum likelihood which has not been output yet. In accordance with these instructions, the retry controller 105 causes the reliability value converter 80 to convert the reliability value data, which has been output again, on the basis of the above candidate string.

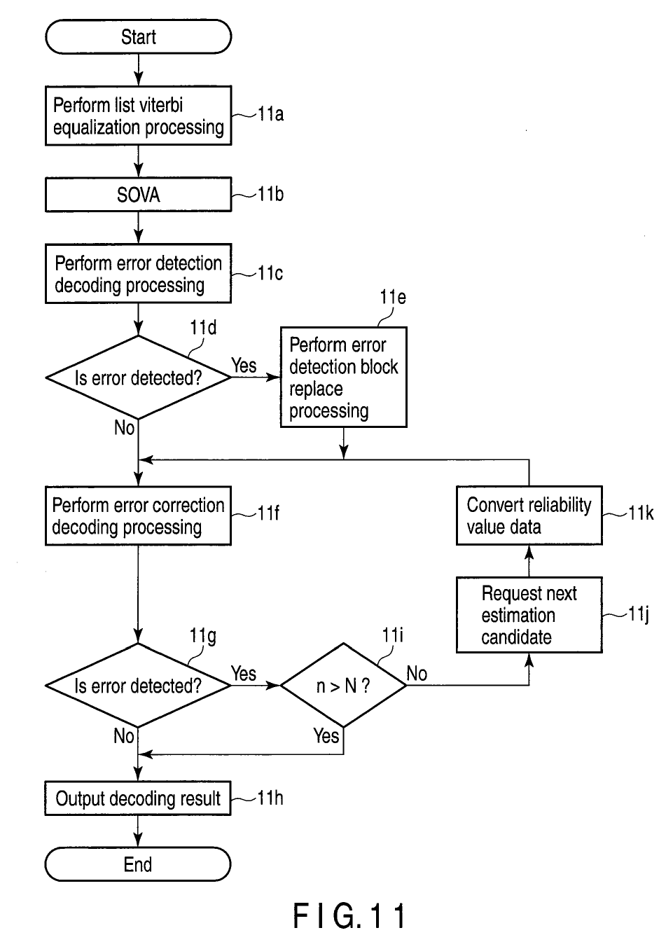

The operation of the receiving-side apparatus having the above arrangement will be described next with reference to FIG. 11. The processing shown in FIG. 11 is executed for each bit sequence to be decoded.

First of all, in step 11a, in accordance with an instruction from the retry controller 105, the list Viterbi equalizer 60 obtains a plurality of candidate strings indicating a candidate of the above bit sequence by performing hard decision by list Viterbi equalization for the bit sequence on the basis of the detection result obtained by the detector 40. The process then shifts to step 11b.

In step 11b, in accordance with an instruction from the retry controller 105, the SOVA equalizer 50 obtains maximum likelihood sequence data by hard decision on each bit of the above bit sequence as a decoding target by maximum likelihood sequence estimation and reliability value data indicating the reliability of each bit of the maximum likelihood sequence data, on the basis of the detection result obtained by the detector 40. The process then shifts to step 11c.

In step 11c, the error detection decoder 75 performs error detection decoding for each of a plurality of candidate strings obtained by the list Viterbi equalizer 60 in step 11a to detect whether each candidate string contains an error. The process then shifts to step 11d.

In step 11d, the error detection decoder 75 checks the result of the processing in step 11c, and, if it determines that a candidate string contains an error, the error detection decoder 75 notifies the error detection block replacement unit 77 of the corresponding information. The process then shifts to step 11e. If the candidate string contains no error, the error detection decoder 75 notifies the error detection block replacement unit 77 of the corresponding information. The process shifts to step 11f.

In step 11e, the error detection block replacement unit 77 divides a plurality of candidate strings obtained by the list Viterbi equalizer 60 into three bit strings, and preferentially combines bit strings without error on the basis of a notification from the error detection decoder 75, thereby performing replace processing. The process then shifts to step 11f.

In step 11f, the soft decision error correction decoder 90 obtains a bit sequence by performing error correction decoding based on the reliability value data output from the reliability value converter 80. The process then shifts to step 11g. Note that when the process shifts from step 11d, the soft decision error correction decoder 90 decodes the reliability value data output from the reliability value converter 80 without conversion, whereas when the process shifts from step 11k, the reliability value converter 80 decodes the reliability value data.

In step 11g, the soft decision error correction decoder 90 notifies the retry controller 105 as to whether a normal decoding result without error has been obtained. If a normal decoding result has not been obtained, i.e., an error has been detected from the decoding result, the process shifts to step 11i. If no error has been detected from the decoding result, the process shifts to step 11h.

In step 11h, the soft decision error correction decoder 90 outputs the bit sequence obtained by decoding to a data processing unit (not shown) on the subsequent stage. The processing is then terminated, and processing for the next bit sequence is started again.

In step 11i, the retry controller 105 increments a parameter n indicating the number of times of conversion executed by the retry controller 105, and determines whether the value exceeds a threshold N. If the parameter n does not exceed the threshold N, the process shifts to step 11j. If the parameter n exceeds the threshold N, the process shifts to step 11h. In this case, in step 11h, a decoding result containing an error is output. In subsequent processing, therefore, a retransmission request is issued to the transmitting side.

In step 11j, the retry controller 105 instructs the reliability value converter 80 to perform conversion based on the nth candidate string, of the candidate strings obtained by replace processing by the error detection block replacement unit 77, which has not been selected. The process then shifts to step 11k.

In step 11k, the reliability value converter 80 selects an upper candidate string (nth candidate), of the candidate strings obtained by replace processing by the error detection block replacement unit 77, which has not been selected in accordance with the instruction from the retry controller 105, and converts the reliability value data obtained by the SOVA equalizer 51, on the basis of the selected candidate string. The reliability value converter 80 then outputs the converted reliability value data to the soft decision error correction decoder 90. The process then shifts to step 11f. With this operation, the soft decision error correction decoder 90 performs error correction decoding on the reliability value data converted in accordance with the candidate strings obtained by replace processing by the error detection block replacement unit 77.

As described above, the decoding apparatus having the above arrangement includes the SOVA equalizer 51 which obtains reliability value data indicating the reliability of each bit of the maximum likelihood sequence data of a bit sequence, the list Viterbi equalizer 60 which obtains a plurality of candidate strings indicating a candidate of the bit sequence, and the error detection block replacement unit 77 which performs replace processing for candidate strings for each bit string constituting the above bit sequence. If normal data cannot be obtained by decoding based on the above reliability value data, the apparatus converts the above reliability value data on the basis of candidate strings obtained by preferentially combining bit strings from which no error has been detected. Based on the resultant data, the soft decision error correction decoder 90 then performs decoding.

The decoding apparatus having the above arrangement therefore can efficiently perform Viterbi equalization processing in spite of using list Viterbi equalization and the error correction scheme requiring soft-valued reliability information.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A decoding apparatus for obtaining a decoded bit string from an input signal, comprising:
a first equalization unit configured to obtain an equalized bit string subjected to hard decision by equalizing the input signal, and to obtain reliability value data as soft decision which is indicating reliability of the hard decision with respect to each bit of the equalized bit string;
a second equalization unit configured to obtain a plurality of candidates of the equalized bit string subjected to hard decision by equalizing the first signal;
a conversion unit configured to covert the reliability value data corresponding to the candidates of the equalized bit string;
a decoding unit configured to obtain a bit string by performing error correction decoding by using the converted reliability value data as soft decision;
a determination unit configured to determine whether the bit string obtained by the decoding unit contains an error; and
a control unit configured to control the conversion unit and the decoding unit based on a determination result obtained by the determination unit to repeatedly execute processing of causing the conversion unit to convert the reliability value data corresponding to the candidate of the equalized bit string and causing the decoding unit to decode the reliability value data converted by the conversion unit, until a bit string without error is obtained.

2. The apparatus according to claim 1, wherein the conversion unit converts the reliability value data by preferentially using the candidates of the equalized bit string in descending order of reliability.

3. The apparatus according to claim 2, which further comprises an attenuation unit configured to attenuate the reliability value data from the conversion unit in accordance with reliability of a candidate used by the conversion unit, and in which
the control unit repeatedly executes processing of causing the conversion unit to convert the reliability value data based on the candidate of the bit string, causing the attenuation unit to perform attenuation, and causing the decoding unit to decode reliability value data attenuated by the attenuation unit, until a bit string without error is obtained.

4. The apparatus according to claim 1, which further comprises
an error detection unit configured to perform error detection on each data block of each of the candidates of the equalized bit string, and
a block replace unit configured to rearrange equalized bit strings by selecting data blocks without error from the candidates of the equalized bit string based on a result of the error detection, and in which
the conversion unit converts the reliability value data by using the equalized bit string rearranged by the block replace unit.

5. A decoding apparatus for obtaining a decoded bit string from an input signal, comprising:
a first equalization unit configured to obtain an equalized bit string subjected to hard decision by performing equalization, and to obtain first reliability value data as soft decision which is indicating reliability of the hard decision with respect to each bit of the equalized bit string;
a second equalization unit configured to obtain a plurality of candidates of the equalized bit string subjected to hard decision by equalizing the first signal;
a conversion unit configured to convert the first reliability value data corresponding to the candidate of the equalized bit string;
a decoding unit configured to obtain a bit string by performing error correction decoding by using the converted reliability value data as soft decision, and to obtain second reliability value data indicating reliability of the soft decision with respect to each bit of the error correcting decoded bit string;
a determination unit configured to determine whether a bit string obtained by the decoding unit contains an error; and
a control unit configured to control the first equalization unit, the conversion unit, and the decoding unit based on a determination result obtained by the determination unit to repeatedly execute first processing of causing the first equalization unit to equalize the input signal while causing the decoding unit to decode the first reliability value data, and when the (no antecedent basis) bit string contains an error, causing the first equalization unit to equalize the second reliability value data while causing the decoding unit to decode the first reliability value data obtained by the equalization, a predetermined number of times until a bit string without error is obtained, and to, when a bit string without error is not obtained by the first processing, repeatedly execute second processing of causing the conversion unit to convert the first reliability value data corresponding to the candidate of the equalized bit string while causing the decoding unit to decode the first reliability value data converted by the conversion unit, a predetermined number of times until the bit string without error is obtained.

6. A decoding apparatus for obtaining a decoded bit string from an input signal, comprising:
a first equalization unit configured to obtain an equalized bit string subjected to hard decision by performing equalization, and to obtain first reliability value data as soft decision which is indicating reliability of the hard decision with respect to each bit of the equalized bit string;
a second equalization unit configured to obtain a plurality of candidates of the equalized bit string subjected to hard decision by equalizing the input signal;
a conversion unit configured to convert the first reliability value data corresponding to the candidates of the equalized bit string;
a decoding unit configured to obtain a bit string by performing error correction decoding by using the converted reliability value data as soft decision as soft decision, and to obtain second reliability value data indicating reliability of the soft decision with respect to each bit of the error correcting decoded bit string;
a determination unit configured to determine whether the bit string obtained by the decoding unit contains an error; and
a control unit configured to control the first equalization unit, the conversion unit, and the decoding unit based on a determination result obtained by the determination unit to repeatedly execute first processing of causing the first equalization unit to equalize the input signal while causing the conversion unit to convert the first reliability value data corresponding to the candidate of the equalized bit string and causing the decoding unit to decode the first reliability value data converted by the conversion unit, a predetermined number of times until a bit string without error is obtained, and to, when a bit string without error is not obtained by the first processing, repeatedly execute second processing of causing the first equalization unit to equalize the second reliability value data while causing the decoding unit to decode the equalized second reliability value data, a predetermined number of times until a bit string without error is obtained.

7. A decoding method of obtaining a decoded bit string from an input signal, comprising:
obtaining an equalized bit string subjected to hard decision by equalizing the input signal, and obtaining reliability value data as soft decision which is indicating reliability of the hard decision with respect to each bit of the equalized bit string;
obtaining a plurality of candidates of the equalized bit string subjected to hard decision by equalizing the first signal;
converting the reliability value data corresponding to the candidates of the equalized bit string;
obtaining a bit string by performing error correction decoding by using the converted reliability value data as soft decision;
determining whether the bit string obtained by the error correction decoding contains an error; and
repeatedly executing processing of converting the reliability value data corresponding to the candidate of the equalized bit string and decoding the converted reliability value data, based on a determination result of the determining, until a bit string without error is obtained.

8. A decoding method of obtaining a decoded bit string from an input signal, comprising:
obtaining an equalized bit string subjected to hard decision by performing equalization, and obtaining first reliability value data as soft decision which is indicating reliability of the hard decision with respect to each bit of the equalized bit string;
obtaining a plurality of candidates of the equalized bit string subjected to hard decision by equalizing the first signal;
converting the first reliability value data corresponding to the candidates of the equalized bit string;
obtaining a bit string by performing error correction decoding by using the converted reliability value data as soft decision, and obtaining second reliability value data indicating reliability of the soft decision with respect to each bit of the error correcting decoded bit string;
determining whether the bit string obtained by the error correction decoding contains an error; and
repeatedly executing first processing of equalizing the input signal while decoding the first reliability value data, and when the bit string contains an error, equalizing the second reliability value data while decoding the first reliability value data obtained by the equalization, a predetermined number of times until a bit string without error is obtained, and repeatedly performing, when a bit string without error is not obtained by the first processing, second processing of converting the first reliability value data corresponding to the candidates of the equalized bit string while decoding the converted first reliability value data, a predetermined number of times, until a bit string without error is obtained.

9. A decoding method of obtaining a decoded bit string from an input signal, comprising:
obtaining an equalized bit string subjected to hard decision by performing equalization, and obtaining first reliability value data as soft decision which is indicating reliability of the hard decision with respect to each bit of the equalized bit string;
obtaining a plurality of candidates of the equalized bit string subjected to hard decision by equalizing the input signal;
converting the first reliability value data corresponding to the candidates of the equalized bit string;
obtaining a bit string by performing error correction decoding by using the converted reliability value data as soft decision as soft decision, and obtaining second reliability value data indicating reliability of the soft decision with respect to each bit of the error correcting decoded bit string;
determining whether the bit string obtained by the error correction decoding contains an error; and
repeatedly executing first processing of equalizing the input signal while converting the first reliability value corresponding to the candidates of the equalized bit string and decoding the converted first reliability value data, a predetermined number of times until a bit string without error is obtained, and repeatedly executing, when a bit string without error is not obtained by the first processing, second processing of equalizing the second reliability value data while decoding the equalized second reliability value data, a predetermined number of times until a bit string without error is obtained.
